(19) United States
(12) Patent Application Publication
(10) Pub. No.: US 2024/0105620 A1
(43) Pub. Date: Mar. 28, 2024

(54) INTERCONNECT WITH DISCONNECTED LINER AND METAL CAP

(71) Applicant: International Business Machines Corporation, Armonk, NY (US)

(72) Inventors: Koichi Motoyama, Clifton Park, NY (US); Oscar van der Straten, Guilderland Center, NY (US); Chih-Chao Yang, Glenmont, NY (US)

(21) Appl. No.: 17/955,001

(22) Filed: Sep. 28, 2022

(51) Int. Cl. H01L 23/532; H01L 23/528

(52) U.S. Cl. CPC H01L 23/53238; H01L 23/528; H01L 23/5329

(57) ABSTRACT

An interconnect structure includes a diffusion barrier layer disposed on exterior surfaces of an opening in a dielectric layer. A top surface of the diffusion barrier layer is below a top surface of the opening. A liner layer is disposed on a bottom surface and sidewalls of the diffusion barrier layer. A spacer layer is disposed on the top surface of the diffusion barrier layer and the liner layer and exposed sidewalls of the opening. An interconnect metal is disposed on the liner layer and the spacer layer. A metal cap is disposed on the interconnect metal.

### BACKGROUND

An integrated circuit (IC) (also referred to as a chip or a microchip) includes electronic circuits on a wafer. An IC includes a large number of electronic devices that form the electronic circuits on the wafer. The back-end-of-line (BEOL) is the second portion of IC fabrication where a network of vias and lines (known collectively as interconnect structures) of the IC is formed. The IC's individual devices, such as transistors, capacitors, resistors, etc. are formed in earlier layers of the IC and communicatively coupled with one another using the interconnect structures in the BEOL layers of the wafer. The BEOL layer that includes the interconnection of wiring is referred to as the metallization layer, which generally begins when the first layer of metal is deposited on the wafer. BEOL layers of the IC generally include contacts, insulating layers (dielectrics), metal levels, bonding sites for chip-to-package connections, etc.

### SUMMARY

Illustrative embodiments of the present application include techniques for use in semiconductor manufacture. In an illustrative embodiment, an interconnect structure comprises a diffusion barrier layer disposed on exterior surfaces of an opening in a dielectric layer. A top surface of the diffusion barrier layer is below a top surface of the opening. The interconnect structure further comprises a liner layer disposed on a bottom surface and sidewalls of the diffusion barrier layer. The interconnect structure further comprises a spacer layer disposed on the top surface of the diffusion barrier layer and the liner layer and exposed sidewalls of the opening. The interconnect structure further comprises an interconnect metal disposed on the liner layer and the spacer layer. The interconnect structure further comprises a metal cap disposed on the interconnect metal.

In another illustrative embodiment, an interconnect structure comprises a diffusion barrier layer disposed on exterior surfaces of an opening in a dielectric layer. The interconnect structure further comprises a liner layer disposed on a bottom surface and a portion of sidewalls of the diffusion barrier layer. The interconnect structure further comprises a spacer layer disposed on a top surface of the liner layer and the remaining portion of the sidewalls of the diffusion barrier layer. The interconnect structure further comprises an interconnect metal disposed on the liner layer and the spacer layer. The interconnect structure further comprises a metal cap disposed on the interconnect metal.

In yet another illustrative embodiment, an interconnect structure comprises a diffusion barrier layer disposed on exterior surfaces of an opening in a dielectric layer. A top surface of the diffusion barrier layer being below a top surface of the opening. The interconnect structure further comprises a liner layer disposed on a bottom surface and sidewalls of the diffusion barrier layer. The interconnect structure further comprises a dielectric cap disposed on the top surface of the diffusion barrier layer and the liner layer and exposed sidewalls of the opening. The interconnect structure further comprises an interconnect metal disposed on the liner layer and the dielectric cap. The interconnect structure further comprises a metal cap disposed on the interconnect metal.

Other embodiments will be described in the following detailed description of embodiments, which is to be read in conjunction with the accompanying figures.

### BRIEF DESCRIPTION OF THE DRAWINGS

FIG. 1 depicts a side cross-sectional view of a semiconductor structure for use at a first-intermediate fabrication stage, according to an illustrative embodiment.

FIG. 2 depicts a side cross-sectional view of a semiconductor structure for use at a second-intermediate fabrication stage, according to an illustrative embodiment.

FIG. 3 depicts a side cross-sectional view of a semiconductor structure for use at a third-intermediate fabrication stage, according to an illustrative embodiment.

FIG. 4 depicts a side cross-sectional view of a semiconductor structure for use at a fourth-intermediate fabrication stage, according to an illustrative embodiment.

FIG. 5 depicts a side cross-sectional view of a semiconductor structure for use at a fifth-intermediate fabrication stage, according to an illustrative embodiment.

FIG. 6 depicts a side cross-sectional view of a semiconductor structure for use at a sixth-intermediate fabrication stage, according to an illustrative embodiment.

FIG. 7 depicts a side cross-sectional view of a semiconductor structure for use at a seventh-intermediate fabrication stage, according to an illustrative embodiment.

FIG. 8 depicts a side cross-sectional view of a semiconductor structure for use at an eighth-intermediate fabrication stage, according to an illustrative embodiment.

FIG. 9 depicts a side cross-sectional view of a semiconductor structure starting from FIG. 4 for use at a first-intermediate fabrication stage, according to an illustrative alternative embodiment.

FIG. 10 depicts a first side cross-sectional view of a semiconductor structure for use at a second-intermediate fabrication stage, according to the illustrative alternative embodiment.

FIG. 11 depicts a first side cross-sectional view of a semiconductor structure for use at a third-intermediate fabrication stage, according to the illustrative alternative embodiment.

FIG. 12 depicts a first side cross-sectional view of a semiconductor structure for use at a fourth-intermediate fabrication stage, according to the illustrative alternative embodiment.

FIG. 13 depicts a side cross-sectional view of a semiconductor structure starting from FIG. 4 for use at a first-intermediate fabrication stage, according to yet another illustrative alternative embodiment.

FIG. 14 depicts a first side cross-sectional view of a semiconductor structure for use at a second-intermediate fabrication stage, according to the yet another illustrative alternative embodiment.

FIG. 15 depicts a first side cross-sectional view of a semiconductor structure for use at a third-intermediate fabrication stage, according to the yet another illustrative alternative embodiment.

### DETAILED DESCRIPTION

Illustrative embodiments of the invention may be described herein in the context of illustrative methods for forming interconnects with a disconnected liner and metal cap to prevent diffusion of the metal from the metal cap into the liner, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description. It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment. The term “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present concept.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

In the IC chip fabrication industry, there are three sections referred to in a typical IC chip build: front-end-of-line (FEOL), back-end-of-line (BEOL), and the section that connects those two together, the middle-of-line (MOL). The FEOL is made up of the semiconductor devices, e.g., transistors, the BEOL is made up of interconnects and wiring, and the MOL is an interconnect between the FEOL and BEOL that includes material to prevent the diffusion of BEOL metals to FEOL devices. Accordingly, illustrative embodiments described herein may be directed to BEOL semiconductor processing and structures. BEOL is the second portion of IC fabrication where the individual devices (e.g., transistors, capacitors, resistors, etc.) become interconnected with wiring on the wafer, e.g., the metallization layer or layers. BEOL includes contacts, insulating layers (dielectrics), metal levels, and bonding sites for chip-to-package connections. In the BEOL, part of the fabrication stage contacts (pads), interconnect wires, vias and dielectric structures are formed. For modern IC processes, more than 10 metal layers may be added in the BEOL.

Embodiments described below may be applicable to FEOL processing and structures, BEOL processing and structures, or both FEOL and BEOL processing and structures. In particular, although an exemplary processing scheme may be illustrated using a FEOL processing scenario, such approaches may also be applicable to BEOL processing. Likewise, although an exemplary processing scheme may be illustrated using a BEOL processing scenario, such approaches may also be applicable to FEOL processing.

Integrated circuits are typically fabricated with multiple levels of patterned metallization lines, electrically separated from one another by interlayer dielectrics containing vias at selected locations to provide electrical connections between levels of the patterned metallization lines. As these integrated circuits are scaled to smaller dimensions in a continual effort to provide increased density and performance (e.g., by increasing device speed and providing greater circuit functionality within a given area chip), the interconnect line width dimension becomes increasingly narrow, which in turn renders them more susceptible to deleterious effects such as electromigration.

Electromigration is a term referring to the phenomenon of mass transport of metallic atoms (e.g., copper or aluminum) which make up the interconnect material, as a result of unidirectional or DC electrical current conduction therethrough. More specifically, the electron current collides with the diffusing metal atoms, thereby pushing them in the direction of current travel. Over an extended period of time, the accumulation of metal at the anode end of the interconnect material significantly increases the local mechanical stress in the system. This in turn may lead to delamination, cracking, and even metal extrusion from the metal wire, thereby causing an electrical short to adjacent interconnects. Electromigration becomes increasingly more significant in integrated circuit design, as relative current densities through metallization lines continue to increase as the linewidth dimensions shrink.

For BEOL pitch below 30 nanometers (nm), it is very challenging to fabricate void-free and highly reliable copper interconnects. It is known that a ruthenium liner enables better copper fill compared to a cobalt liner. However, for cases using a cobalt cap and ruthenium liner for copper interconnects, the cobalt easily diffuses into the ruthenium liner from the cap, which facilitates copper migration at the top of liner and results in poor electromigration performance.

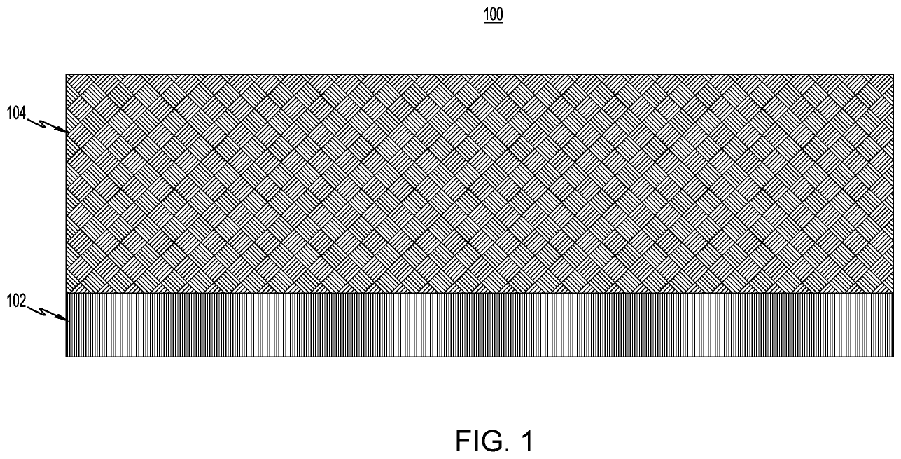

The non-limiting illustrative embodiments descried herein overcome the foregoing drawbacks. Referring now to the drawings in which like numerals represent the same of similar elements, FIGS. 1-15 illustrate various processes for fabricating semiconductor structures having an interconnect with a disconnected liner and metal cap to prevent diffusion of the metal from the metal cap into the liner. Note that the same reference numeral (100) is used to denote the semiconductor structure through the various intermediate fabrication stages illustrated in FIGS. 1-15. Note also that the semiconductor structure described herein can also be considered to be a semiconductor device and/or an integrated circuit, or some part thereof. For the purpose of clarity, some fabrication steps leading up to the production of the semiconductor structures as illustrated in FIGS. 1-15 are omitted. In other words, one or more well-known processing steps which are not illustrated but are well-known to those of ordinary skill in the art have not been included in the figures. This is not intended to be interpreted as a limitation of any particular embodiment, or illustration, or scope of the claims.

Referring now to FIGS. 1-8 in one non-limiting illustrative embodiment, FIG. 1 is a cross-sectional view of a semiconductor structure 100 at a first-intermediate fabrication stage. During this stage, a dielectric layer 104 is formed on substrate 102. The substrate 102 may be formed of any suitable semiconductor materials, including various silicon-containing materials including but not limited to silicon (Si), silicon germanium (SiGe), silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), zinc selenide (ZnSe), etc. In one illustrative embodiment, substrate 102 is silicon.

Dielectric layer 104 can be deposited utilizing any conventional deposition technique such as physical vapor deposition (PVD), atomic layer deposition (ALD) and chemical vapor deposition (CVD). The dielectric layer 104 can be planarized using, for example, a planarizing process such as chemical mechanical planarization (CMP) or any other suitable planarization process. Other planarization processes can include grinding and polishing.

Dielectric layer 104 can be a low-k dielectric material. The dielectric constant (k) of the low-k dielectric material can be equal to or less than about 2.5 in one or more illustrative embodiments. Also, the dielectric constant (k) of the low-k dielectric material can be equal to or less than about 2.7 in one or more illustrative embodiments. Further, the dielectric constant (k) of the low-k dielectric material can be equal to or less than about 3.0, 3.7, and/or 3.9 in one or more other illustrative embodiments. Suitable materials of the low-k dielectric material include, for example, porous SiCN, SiO₂, SiCOH, SiCO, and octamethylcyclotetrasiloxane (OMCTS).

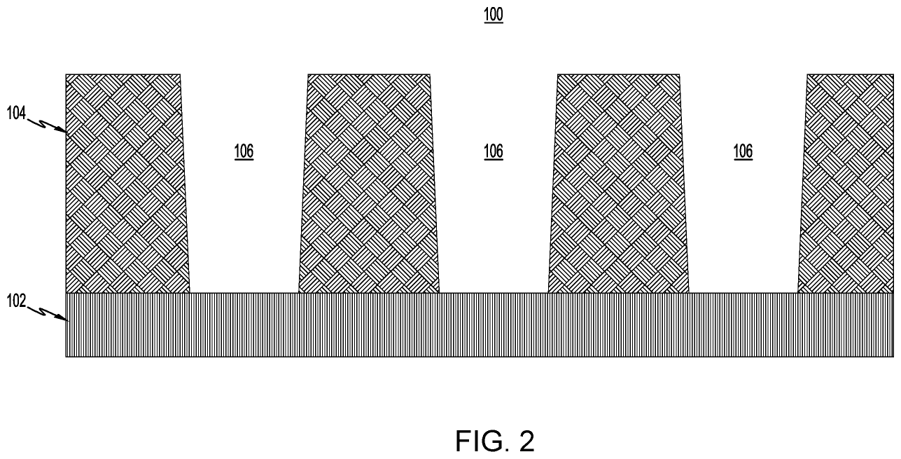

FIG. 2 illustrates semiconductor structure 100 at a second-intermediate fabrication stage. During this stage, openings 106 are formed in dielectric layer 104 utilizing conventional lithographic and etching processes. For example, a hard mask layer is deposited on dielectric layer 104 followed by lithographic processing to result in a patterned hard mask layer. The material of the hard mask layer may include SiN, a multi-layer of SiN and SiO₂, or another suitable material. Once the hard mask layer is patterned, a cut is performed to form openings 106. The hard mask layer can then be removed by any suitable etching technique, followed by planarization using chemical mechanical planarization (CMP) or any other suitable planarization process.

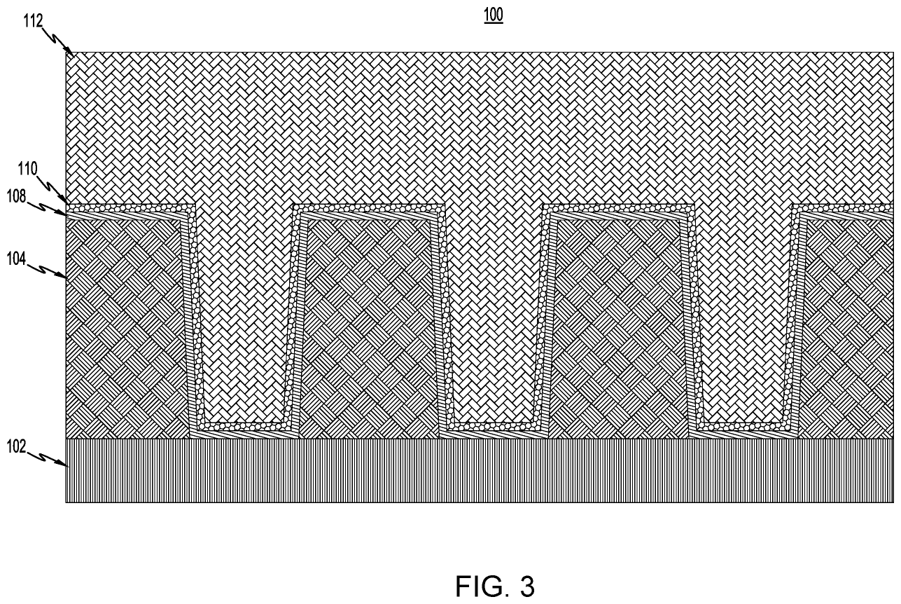

FIG. 3 illustrates semiconductor structure 100 at a third-intermediate fabrication stage. During this stage, a diffusion barrier layer 108 is first deposited on the exterior surface of the openings 106 using conventional deposition techniques such as ALD, CVD, PVD, plasma enhanced chemical vapor deposition (PECVD), sputtering, chemical solution deposition or plating. Diffusion barrier layer 108 can be formed from, for example, titanium nitride, tantalum nitride, or any other appropriate material to serve as a diffusion barrier that prevents any conductive material from diffusing into the neighboring dielectric material. The thickness of the diffusion barrier layer 108 may vary depending on the deposition process used as well as the material employed. In some embodiments, the diffusion barrier layer 108 may have a thickness from 0.5 nm to about 3 nm; although other thicknesses for the diffusion barrier layer 108 are contemplated and can be employed as long as the diffusion barrier material does not entirely fill the opening.

Next, a liner layer 110 is formed on the surface of the diffusion barrier layer 108. The liner layer 110 can be employed to selectively promote subsequent electroplating of a pre-selected conductive metal or metal alloy. Suitable material for liner layer 110 may be composed of Ru, a Ru alloy (e.g., TaRu alloy) or any other suitable noble metal or noble metal alloy having a low metal-plating overpotential. The thickness of the liner layer 110 may vary depending on the material of the liner layer as well as the technique used in forming it. In some embodiments, the liner layer 110 may have a thickness from 0.5 nm to about 3 nm; although other thicknesses for the liner layer 110 are contemplated. The liner layer 110 can be formed by a conventional deposition process including, for example, CVD, PECVD, ALD, or PVD.

An interconnect metal 112 is formed into each opening 106 and on liner layer 110. The interconnect metal 112 may be composed of, for example, copper (Cu), aluminum (Al), tungsten (W), or an alloy thereof such as, for example, a Cu—Al alloy. The interconnect metal 112 can be formed utilizing a deposition process such as, for example, ALD, CVD, PECVD, sputtering, chemical solution deposition or plating. In one embodiment, the combination of a PVD Cu seed and a bottom-up plating process is employed in forming the interconnect metal 112.

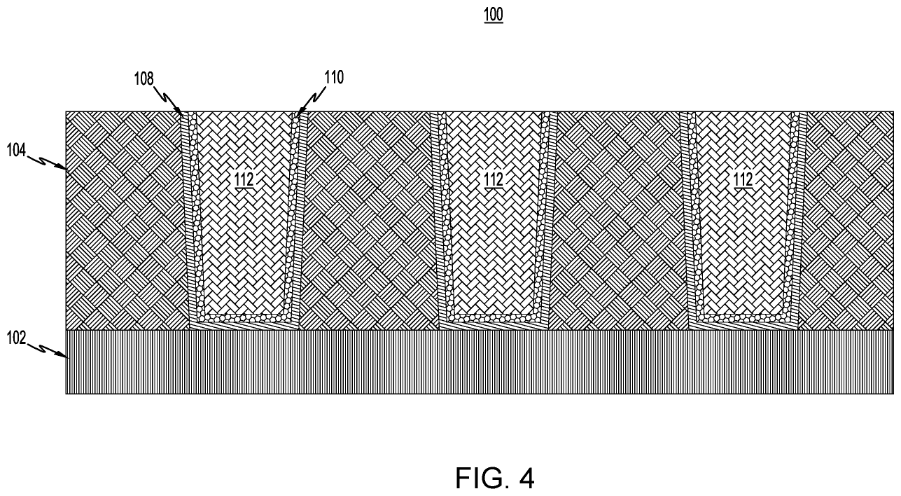

FIG. 4 illustrates semiconductor structure 100 at a fourth-intermediate fabrication stage. During this stage, a planarization process such as, for example, CMP and/or grinding, can be used to remove all interconnect metal 112 as well as diffusion barrier layer 108 and liner layer 110 (i.e., overburden material) that is present outside each of the openings 106.

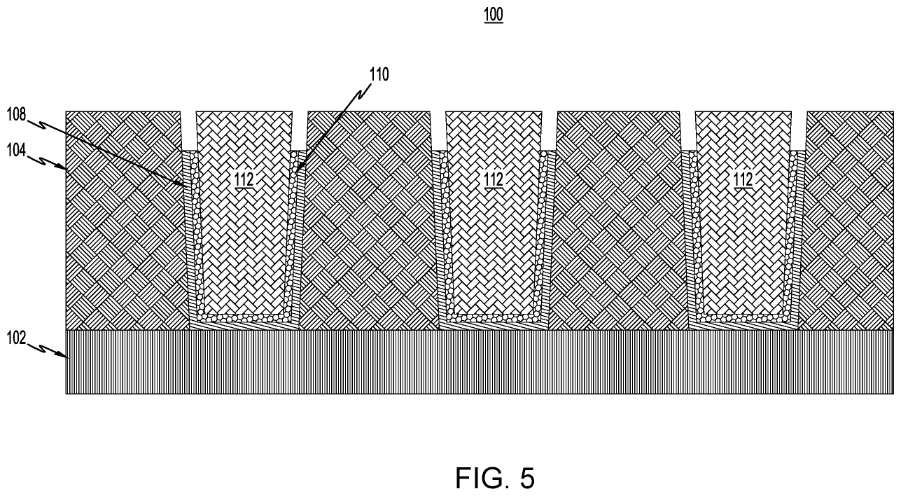

FIG. 5 illustrates semiconductor structure 100 at a fifth-intermediate fabrication stage. During this stage, diffusion barrier layer 108 and liner layer 110 are selectively recessed relative to dielectric layer 104 and interconnect metal 112 using a selective etch process such as a wet etch. Diffusion barrier layer 108 and liner layer 110 are selectively recessed to below a top surface of dielectric layer 104 and interconnect metal 112.

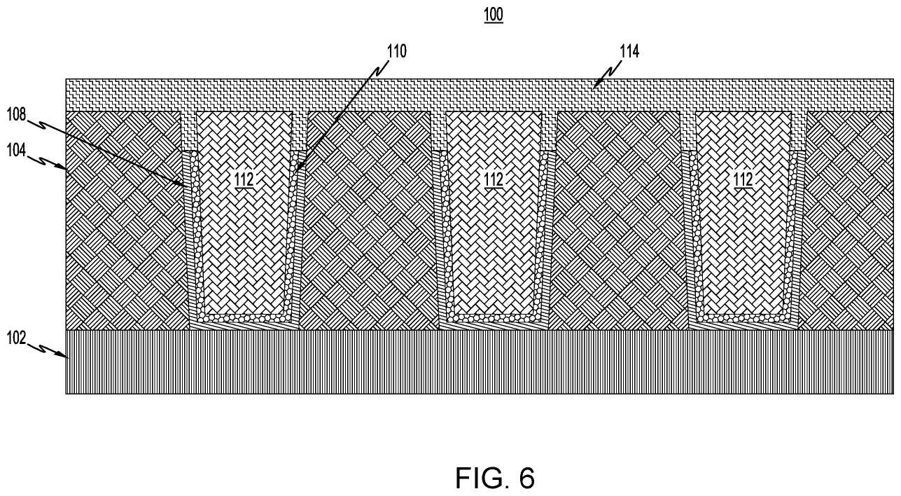

FIG. 6 illustrates semiconductor structure 100 at a sixth-intermediate fabrication stage. During this stage, spacer layer 114 is deposited in the recessed portion of diffusion barrier layer 108 and liner layer 110 and over the top surface of semiconductor structure 100. Suitable material for spacer layer 114 includes, for example, SiN, SiNO, SiCN, AlOx, and HfOx. The spacer layer 114 can be formed utilizing a conventional deposition process such as, for example, ALD, CVD, PVD and PECVD.

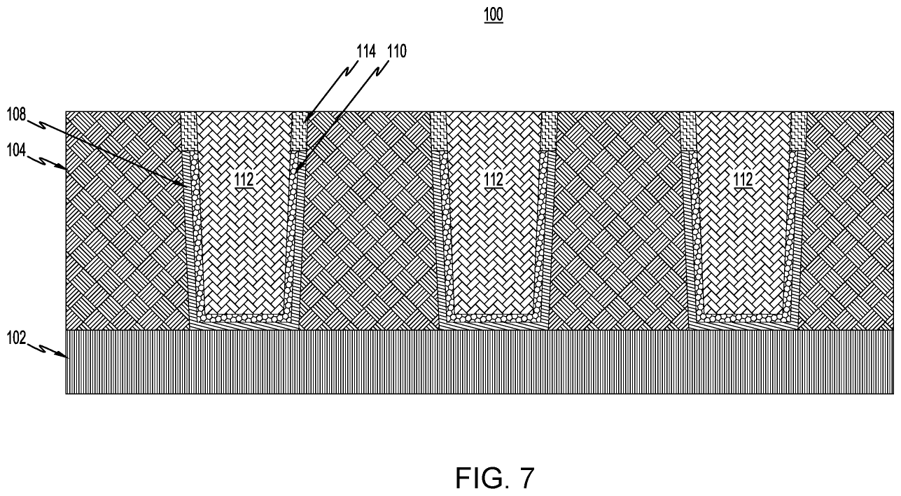

FIG. 7 illustrates semiconductor structure 100 at a seventh-intermediate fabrication stage. During this stage, a planarization process such as, for example, CMP and/or grinding, can be used to remove all spacer layer 114 (i.e., overburden material) that is present on the top surface of semiconductor structure 100.

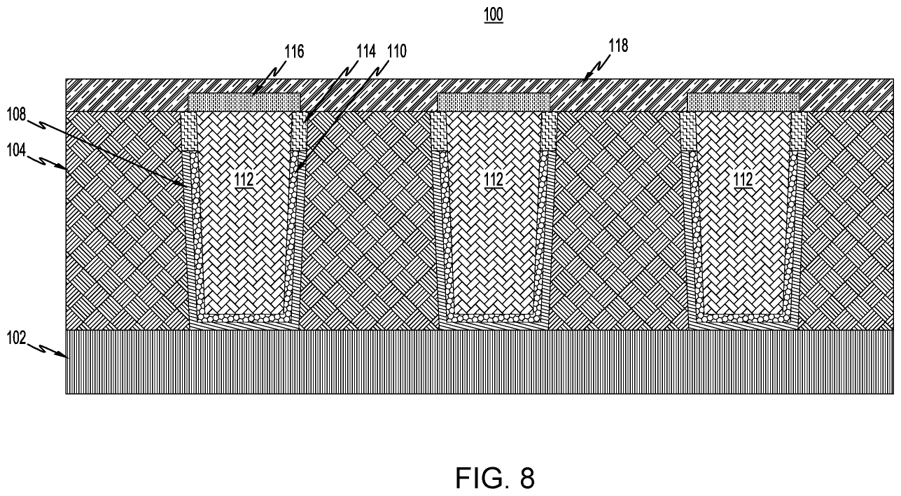

FIG. 8 illustrates semiconductor structure 100 at an eighth-intermediate fabrication stage. During this stage, a metal cap 116 is selectively deposited on interconnect metal 112. The selective area deposition of the metal cap 116 in combination with the spacer layer 114 encapsulates the interconnect metal 112 preventing it from being exposed during subsequent processing as well as preventing electromigration. Suitable metals for the selective area deposition of the metal cap 116 will generally depend on the underlying metal and is selected to provide etch selectivity relative to the underlying interconnect metal 112. Exemplary metals include, but are not limited to, cobalt, ruthenium, multilayers thereof such as a cobalt-ruthenium bilayer, alloys thereof, and the like. In one or more illustrative embodiments, the thickness (e.g., vertical height) of the metal cap 116 can range from about 1 nm to about 5 nm, but thicker or thinner layers may be used as well. The metal cap 116 can be deposited by any conventional deposition process such as, for example, ALD, CVD, PVD and PECVD.

Next, dielectric cap 118 is formed on the exposed surfaces of metal cap 116, spacer layer 114 and dielectric layer 104 by blanket or non-selective CVD. Suitable material for dielectric cap 118 includes, for example, a silicon-containing dielectric material such as silicon nitride (SiN), silicon carbide (SiC), silicon oxynitride (SiNO) or amorphous silicon carbonitride (SiCyNx:H). In one or more illustrative embodiments, the thickness (e.g., vertical height) of the dielectric cap 118 can range from about 1 nm to about 5 nm, but thicker or thinner layers may be used as well.

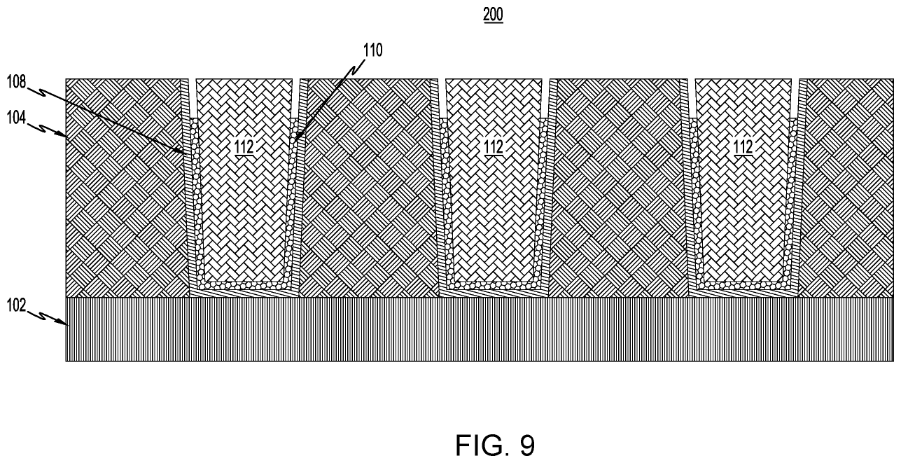

Referring now to FIGS. 9-12 illustrating an alternative non-limiting illustrative embodiment starting from FIG. 4, FIG. 9 illustrates semiconductor structure 200 at a first-intermediate fabrication stage. During this stage, liner layer 110 is selectively recessed by, for example, a wet etching process such as a wet isotropic etching or another suitable process.

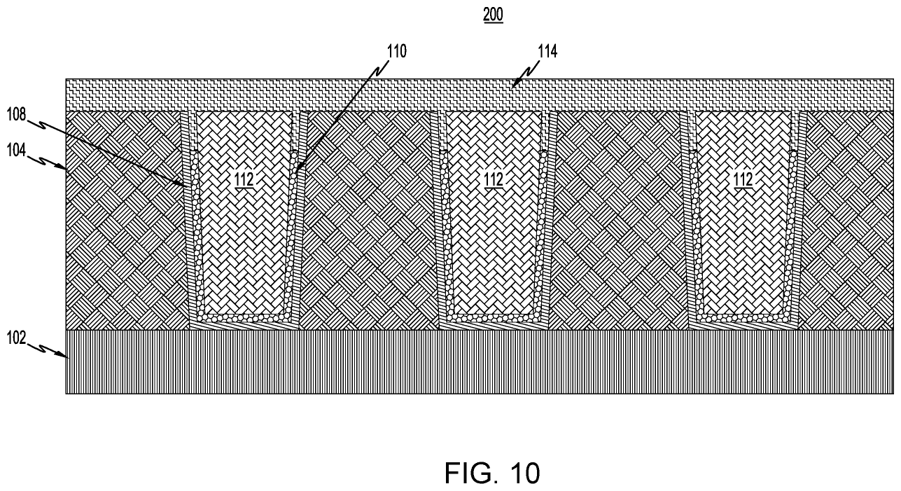

FIG. 10 illustrates semiconductor structure 100 at a second-intermediate fabrication stage. During this stage, spacer layer 114 is deposited in the recessed portion of liner layer 110 and over the top surface of semiconductor structure 100. Suitable material and deposition processes for spacer layer 114 can be any of those discussed above.

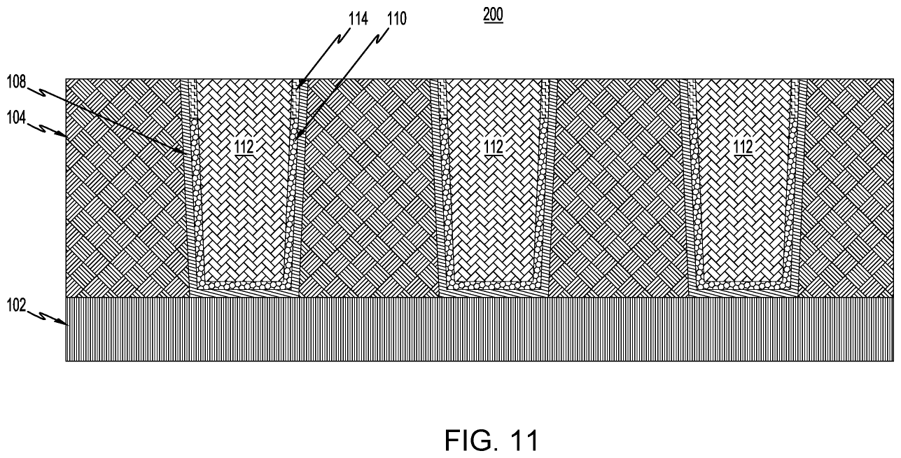

FIG. 11 illustrates semiconductor structure 100 at a third-intermediate fabrication stage. During this stage, a planarization process such as, for example, CMP and/or grinding, can be used to remove all of spacer layer 114 (i.e., overburden material) that is present on the top surface of semiconductor structure 100.

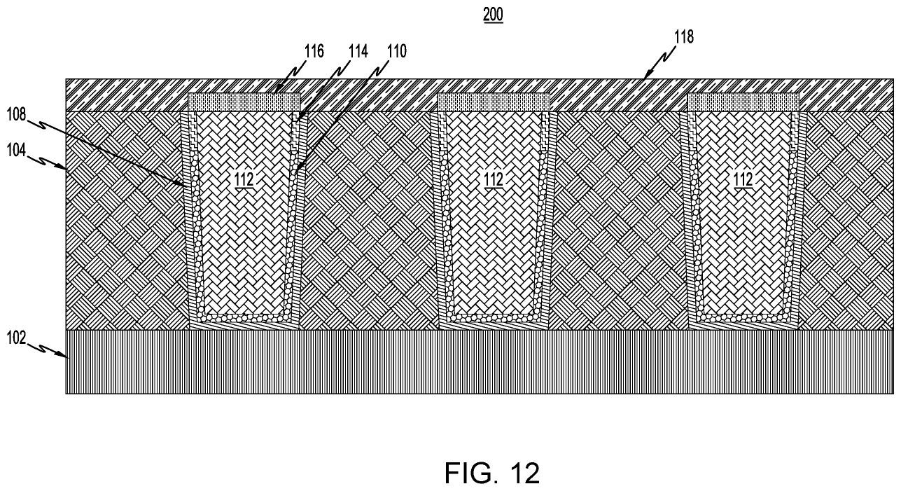

FIG. 12 illustrates semiconductor structure 100 at a fourth-intermediate fabrication stage. During this stage, a metal cap 116 is selectively deposited on interconnect metal 112. The selective area deposition of the metal cap 116 in combination with the spacer layer 114 encapsulates the interconnect metal 112 preventing it from being exposed during subsequent processing as well as preventing electromigration. Suitable metals and deposition processes for the selective area deposition of the metal cap 116 can be any of those discussed above. In one or more illustrative embodiments, the thickness (e.g., vertical height) of the metal cap 116 can range from about 1 nm to about 5 nm, but thicker or thinner layers may be used as well.

Next, dielectric cap 118 is formed on the exposed surfaces of metal cap 116, spacer layer 114 and dielectric layer 104. Suitable material and deposition processes for dielectric cap 118 can be any of those discussed above. In one or more illustrative embodiments, the thickness (e.g., vertical height) of the dielectric cap 118 can range from about 1 nm to about 5 nm, but thicker or thinner layers may be used as well.

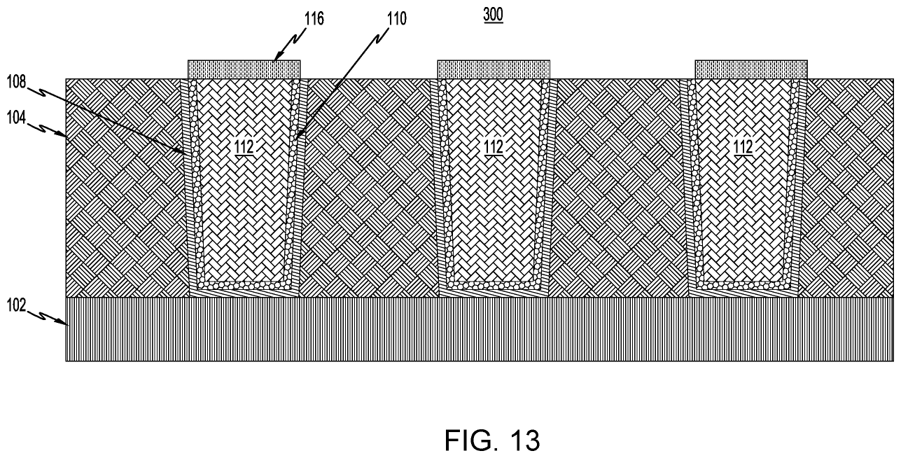

Referring now to FIGS. 13-15 illustrating another alternative non-limiting illustrative embodiment starting from FIG. 4, FIG. 13 illustrates semiconductor structure 300 at a first-intermediate fabrication stage. During this stage, a metal cap 116 is selectively deposited on interconnect metal 112. Suitable metals and deposition processes for the selective area deposition of the metal cap 116 can be any of those discussed above. In one or more illustrative embodiments, the thickness (e.g., vertical height) of the metal cap 116 can range from about 1 nm to about 5 nm, but thicker or thinner layers may be used as well.

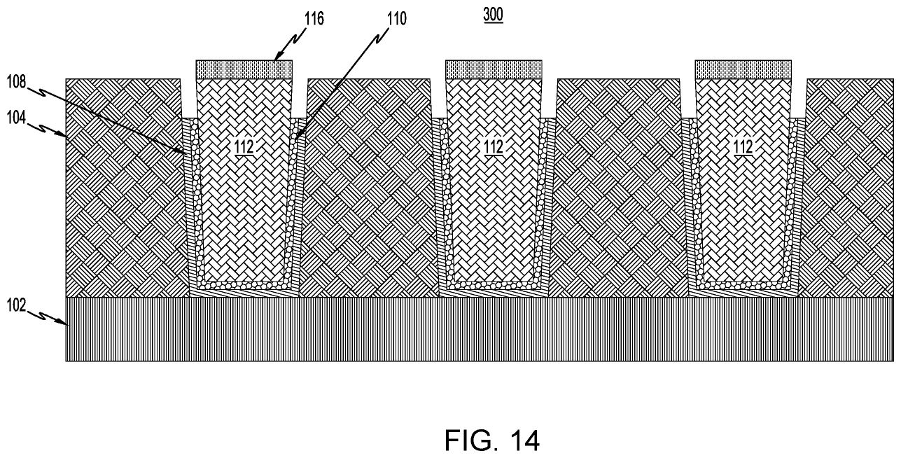

FIG. 14 illustrates semiconductor structure 100 at a second-intermediate fabrication stage. During this stage, diffusion barrier layer 108 and liner layer 110 are selectively recessed by, for example, a wet etching process such as a wet isotropic etching or another suitable process.

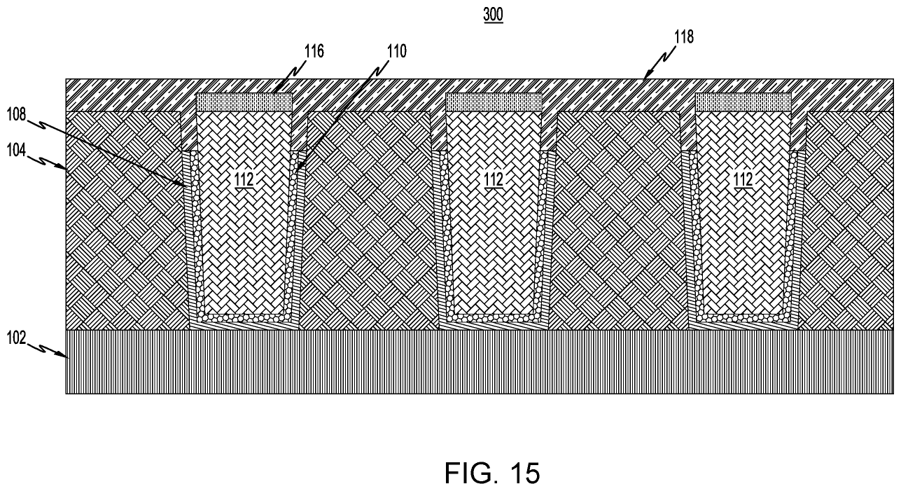

FIG. 15 illustrates semiconductor structure 100 at a third-intermediate fabrication stage. During this stage, a dielectric cap 118 is formed on the exposed surfaces of metal cap 116, diffusion barrier layer 108 and liner layer 110. Suitable material and deposition processes for dielectric cap 118 can be any of those discussed above. In one or more illustrative embodiments, the thickness (e.g., vertical height) of the dielectric cap 118 can range from about 1 nm to about 5 nm, but thicker or thinner layers may be used as well.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. An interconnect structure, comprising:
a diffusion barrier layer disposed on exterior surfaces of an opening in a dielectric layer, a top surface of the diffusion barrier layer being below a top surface of the opening;
a liner layer disposed on a bottom surface and sidewalls of the diffusion barrier layer;
a spacer layer disposed on the top surface of the diffusion barrier layer and the liner layer and exposed sidewalls of the opening;
an interconnect metal disposed on the liner layer and the spacer layer; and
a metal cap disposed on the interconnect metal.

2. The interconnect structure of claim 1, wherein a top surface of the liner layer is coplanar with the top surface of the diffusion barrier layer.

3. The interconnect structure of claim 1, wherein a top surface of the interconnect metal is coplanar with a top surface of the dielectric layer.

4. The interconnect structure of claim 1, further comprising a dielectric cap disposed on the dielectric layer and over the metal cap.

5. The interconnect structure of claim 1, wherein the diffusion barrier layer comprises a material selected from the group consisting of tantalum, tantalum nitride, titanium, titanium nitride, tungsten nitride and combinations thereof.

6. The interconnect structure of claim 1, wherein the liner layer comprises a material selected from the group consisting of ruthenium, rhodium, palladium, and combinations thereof.

7. The interconnect structure of claim 1, wherein the interconnect metal comprises copper.

8. The interconnect structure of claim 1, wherein the liner layer comprises ruthenium and the metal cap comprises cobalt.

9. An interconnect structure, comprising:
a diffusion barrier layer disposed on exterior surfaces of an opening in a dielectric layer;
a liner layer disposed on a bottom surface and a portion of sidewalls of the diffusion barrier layer;
a spacer layer disposed on a top surface of the liner layer and the remaining portion of the sidewalls of the diffusion barrier layer;
an interconnect metal disposed on the liner layer and the spacer layer; and
a metal cap disposed on the interconnect metal.

10. The interconnect structure of claim 9, wherein a top surface of the interconnect metal is coplanar with a top surface of the dielectric layer.

11. The interconnect structure of claim 9, wherein the top surface of the liner layer is below a top surface of the diffusion barrier layer

12. The interconnect structure of claim 9, further comprising a dielectric cap disposed on the dielectric layer and over the metal cap.

13. The interconnect structure of claim 9, wherein the diffusion barrier layer comprises a material selected from the group consisting of tantalum, tantalum nitride, titanium, titanium nitride, tungsten nitride and combinations thereof.

14. The interconnect structure of claim 9, wherein the interconnect metal comprises copper.

15. The interconnect structure of claim 9, wherein the liner layer comprises ruthenium and the metal cap comprises cobalt.

16. An interconnect structure, comprising:
a diffusion barrier layer disposed on exterior surfaces of an opening in a dielectric layer, a top surface of the diffusion barrier layer being below a top surface of the opening;
a liner layer disposed on a bottom surface and sidewalls of the diffusion barrier layer;
a dielectric cap disposed on the top surface of the diffusion barrier layer and the liner layer and exposed sidewalls of the opening;
an interconnect metal disposed on the liner layer and the dielectric cap; and
a metal cap disposed on the interconnect metal.

17. The interconnect structure of claim 16, wherein a top surface of the liner layer is coplanar with the top surface of the diffusion barrier layer.

18. The interconnect structure of claim 16, wherein a top surface of the interconnect metal is coplanar with a top surface of the dielectric layer.

19. The interconnect structure of claim 16, wherein the dielectric cap is further disposed over the metal cap.

20. The interconnect structure of claim 16, wherein the liner layer comprises ruthenium and the metal cap comprises cobalt.
